(19) United States
(12) Patent Application Publication
(10) Pub. No.: US 2026/0013039 A1
(43) Pub. Date: Jan. 8, 2026

(54) SEMICONDUCTOR PACKAGE MODULE, CONDUCTIVE CONNECTING COMPONENT AND METHOD FOR FABRICATION OF THE SAME

(71) Applicant: Universal Global Technology (Kunshan) Co., Ltd., Jiangsu Province (CN)

(72) Inventors: LI-CHENG SHEN, Jiangsu Province (CN); KUO-HSIEN LIAO, Jiangsu Province (CN); HUNG-YI TSAI, Jiangsu Province (CN); CHAO-HSUAN WANG, Jiangsu Province (CN)

(21) Appl. No.: 19/258,866

(22) Filed: Jul. 2, 2025

(30) Foreign Application Priority Data
Jul. 3, 2024 (CN) 202410884719.X

(51) Int. Cl. H05K 1/02; H05K 1/14; H05K 1/18

(52) U.S. Cl. CPC H05K 1/0296; H05K 1/144; H05K 1/181; H05K 2201/042; H05K 2201/10015; H05K 2201/1003

(57) ABSTRACT

A conductive connecting component and a semiconductor package module using this conductive connecting component are provided. The conductive connecting component includes a plurality of patterned metal layers and an encapsulation layer. The patterned metal layers are stacked on each other in one direction, while the encapsulation layer having two opposite surfaces encapsulates the patterned metal layers. These surfaces extend along with the direction where the patterned metal layers are stacked on. Two end surfaces of each patterned metal layer are exposed on the surfaces of the encapsulation layer separately, and these two end surfaces of each patterned metal layer are flush with the surfaces of the encapsulation layer separately.

### RELATED APPLICATIONS

This application claims priority to China Application Serial Number 202410884719.X, filed Jul. 3, 2024, which is herein incorporated by reference in its entirety.

### BACKGROUND

### Technical Field

The present disclosure relates to an electronic package module and a conductive connecting component of the electronic package module. More particular, the present disclosure relates to a semiconductor package module, a conductive connecting component of the semiconductor package module and the methods for fabrication of the same.

### Description of Related Art

When a semiconductor package module includes more than two circuit substrates, the circuit substrates should be electrically connected to each other through a conductive connection component, such as an interposer, which are disposed between the circuit substrates. Printed circuit boards in the form of stamp holes and pin headers are two main types of connecting components in present. The side surface of the printed circuit boards in the form of stamp holes has a plurality of cross-sections of conductive through holes that can be used as paths for the circuit substrates to be electrically connected to each other. Since the cross-sections of the conductive through holes are uneven, it is necessary to fill the holes in the assembly process of the semiconductor package module with materials, such as conductive adhesives or soldering paste, so as to flatten the cross-sections of the conductive through holes.

In addition, two ends of each pin in the pin headers protrude from the surfaces of the encapsulation layer of the pin headers. Thus, two sides of the pin headers are uneven. When the pin header is disposed on the circuit substrate by a surface mount technology (SMT) using placement machine, a mylar should be adhered to one end of the pin header to form a temporary flat surface, so that the vacuum nozzle of the SMT placement machine can draw the pin header easily. Based on the above, the complexity and fabrication cost of these two connecting components in the packaging process are hardly to be reduced.

Furthermore, the encapsulation materials of the outer layer of the pin headers should have a specific thickness (at least 0.3 mm). Therefore, the amount of currents that the pin headers can carry is limited without thickening the pin headers and with limited cross-sections of the internal pins.

### SUMMARY

Accordingly, the disclosure is to provide a semiconductor package module so as to increase the current carrying capacity of the semiconductor package module.

At least one embodiment of the disclosure provides a conductive connecting component disposed inside the aforementioned semiconductor package module and the method for fabricating the conductive connecting component, thereby simplifying the fabricating process of the conductive connecting component.

At least one embodiment of the disclosure provides a conductive connecting component which includes a plurality of patterned metal layers stacked on each other in one direction and an encapsulation layer encapsulating the plurality of patterned metal layers. The encapsulation layer has two first surfaces opposite to each other, and the first surfaces extend along with the direction. Two end surfaces of each of the patterned metal layers are exposed on the first surfaces of the encapsulation layer separately, and the end surfaces of each of the patterned metal layers are flush with the first surfaces of the encapsulation layer separately.

At least one embodiment of the disclosure provides a semiconductor package module which includes a first circuit substrate, a second circuit substrate, a first electronic component, a second electronic component and a conductive connecting component. The second circuit substrate is disposed on the first circuit substrate oppositely, and the second circuit substrate has a third surface and a fourth surface opposite to each other. The first electronic component is disposed on the third surface of the second circuit substrate and electrically connected to the second circuit substrate. The second electronic component is disposed on the fourth surface of the second circuit substrate, while the second electronic component is located between the first circuit substrate and the second circuit substrate and electrically connected to the first circuit substrate and the second circuit substrate. The conductive connecting component is disposed on the fourth surface of the second circuit substrate and located between the first circuit substrate and the second circuit substrate. The end surfaces of each of the patterned metal layers of the conductive connecting component are connected to the first circuit substrate and the second circuit substrate separately, and the first circuit substrate is electrically connected to the second circuit substrate through the patterned metal layers of the conductive connecting component.

At least one embodiment of the disclosure provides a method for fabrication of a conductive connecting component. The method includes providing a plurality of initial patterned metal layers and stacking the plurality of initial patterned metal layers along with a normal direction of the plurality of initial patterned metal layers. The method includes forming an initial encapsulation layer on the plurality of initial patterned metal layers after the plurality of initial patterned metal layers are stacked on each other. The initial encapsulation layer encapsulates the plurality of initial patterned metal layers. The method includes cutting the initial encapsulation layer and the plurality of initial patterned metal layers after the initial encapsulation layer is formed to form an encapsulation layer and a plurality of patterned metal layers. The encapsulation layer has two first surfaces opposite to each other, and the first surfaces extend along with the normal direction. Two end surfaces of each of the patterned metal layers are exposed on the first surfaces of the encapsulation layer separately, and the end surfaces of each of the patterned metal layers are flush with the first surfaces of the encapsulation layer separately.

According to the aforementioned embodiments, the conductive connecting component of at least one embodiment of the disclosure includes a plurality of patterned metal layers stacked on one another and an encapsulation layer encapsulating the plurality of patterned metal layers. The encapsulation layer is used to fasten the plurality of patterned metal layers, so that the patterned metal layers are hardly to be moved. In the fabrication process, the thickness of the encapsulation layer may be reduced without the effects for the fastening of the patterned metal layers since the stacked patterned metal layers are hardly to be moved. Therefore, the thicknesses of the patterned metal layers may be increased so as to increase the current carrying capacity of the conductive connecting component without thickening the conductive connecting component.

### BRIEF DESCRIPTION OF THE DRAWINGS

FIG. 1 illustrates a side view of a semiconductor package module in accordance with one embodiment of the present disclosure.

FIG. 2 illustrates a stereographic view of a conductive connecting component in accordance with one embodiment of the present disclosure.

FIG. 3A illustrates a locally side view of a conductive connecting component in accordance with one embodiment of the present disclosure.

FIG. 3B illustrates a locally side view of a conductive connecting component in accordance with another embodiment of the present disclosure.

FIG. 4A illustrates a stereographic view of a method for fabricating a conductive connecting component in accordance with one embodiment of the present disclosure.

FIG. 4B illustrates a locally cross-sectional view of a method for fabricating a conductive connecting component in accordance with one embodiment of the present disclosure.

FIG. 5A to FIG. 5C illustrate side views of a semiconductor package module in accordance with one embodiment of the present disclosure.

### DETAILED DESCRIPTION

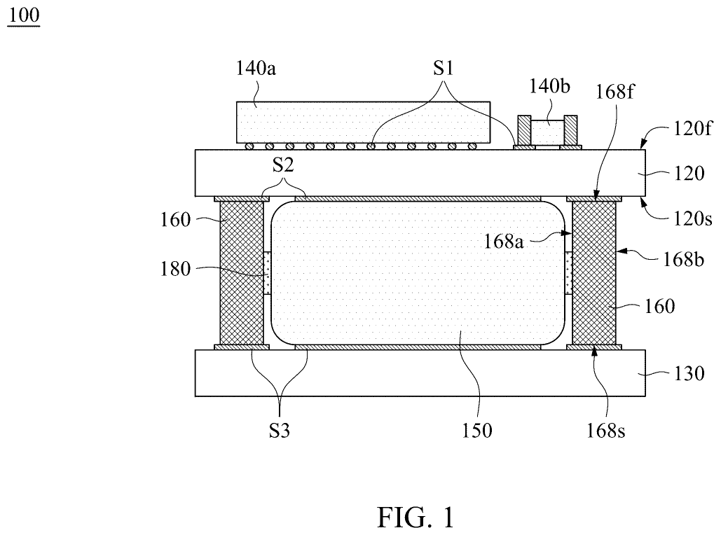

Referring to FIG. 1, a semiconductor package module 100 in accordance with one embodiment of the present disclosure is illustrated. The semiconductor package module 100 includes a circuit substrate 120 and a circuit substrate 130 which are disposed on each other oppositely, a first electronic component 140a (and a first electronic component 140b), a second electronic component 150 and a conductive connecting component 160. The circuit substrate 120 has a surface 120f and a surface 120s which are opposite to each other. That is, the surface 120f and the surface 120s are located at two opposite sides of the circuit substrate 120 separately.

The first electronic component 140a (and the first electronic component 140b) is disposed on the surface 120f of the circuit substrate 120 and is electrically connected to the circuit substrate 120 through a plurality of conductive adhesive materials S1. The second electronic component 150 is disposed on the surface 120s of the circuit substrate 120 and is electrically connected to the circuit substrate 120 through a plurality of conductive adhesive materials S2. The second electronic component 150 is located between the circuit substrate 120 and the circuit substrate 130, and the second electronic component 150 may be electrically connected to the circuit substrate 130 through a plurality of conductive adhesive materials S3. The conductive adhesive materials S1, the conductive adhesive materials S2 and the conductive adhesive materials S3 may be soldering materials, such as copper pastes, silver pastes or soldering balls. However, in some embodiments, the conductive adhesive materials S1, the conductive adhesive materials S2 and the conductive adhesive materials S3 may be conductive adhesives (or conductive glues).

The first electronic component 140a is electrically connected to the circuit substrate 120 through the conductive adhesive materials S1 which are connected to a plurality of pads (not shown) on the surface 120f, but the disclosure is not limited to the embodiment. In other embodiments, the first electronic component 140a may be electrically connected to the circuit substrate 120 by wire-bonding. In addition, the circuit substrate 120 may further include at least one layer of solder mask (not shown). The solder mask may cover the surface 120f of the circuit substrate 120, and the aforementioned pads are exposed.

The first electronic component 140a, the first electronic component 140b and the second electronic component 150 may be active components, such as transistors, or may be passive components, such as capacitors or inductors. For example, in the embodiment, the first electronic component 140a and the first electronic component 140b are disposed on the surface 120f of the circuit substrate 120, while the first electronic component 140a is a packaged chip or an unpackaged die. The first electronic component 140b is a capacitor, while the second electronic component 150 is an inductor. However, the sorts of the first electronic component 140a, the first electronic component 140b and the second electronic component 150 are not limited to the embodiment.

Furthermore, the quantity of the first electronic component 140a, the first electronic component 140b and the second electronic component 150 in the semiconductor package module 100 is not limited to the embodiment. In other words, the semiconductor package module 100 may include more than one first electronic component 140a (or one first electronic component 140b) and more than one second electronic component 150, such as two second electronic components 150, in other embodiments.

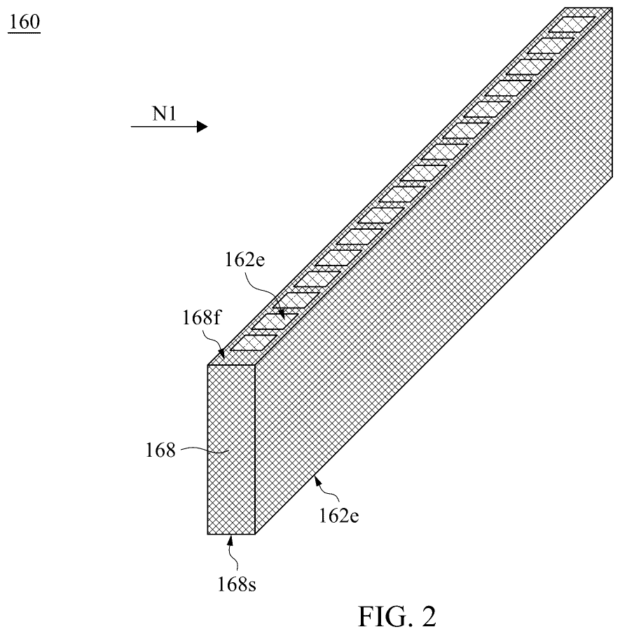

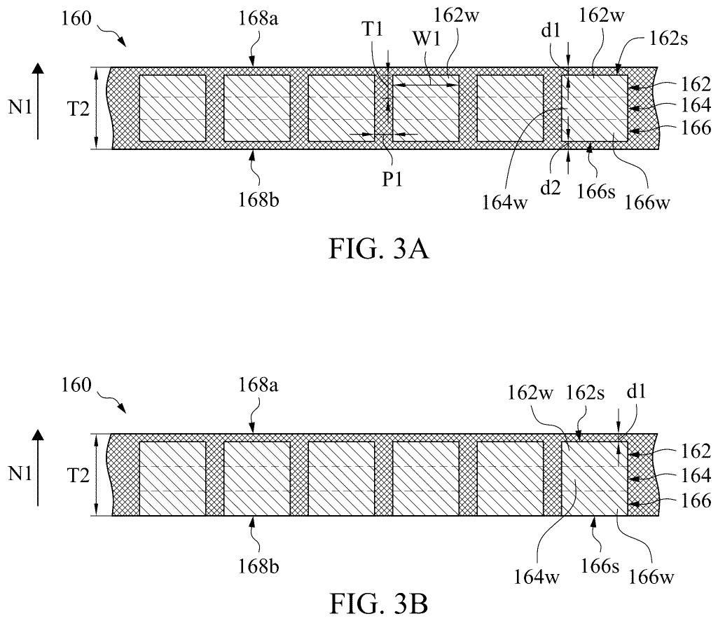

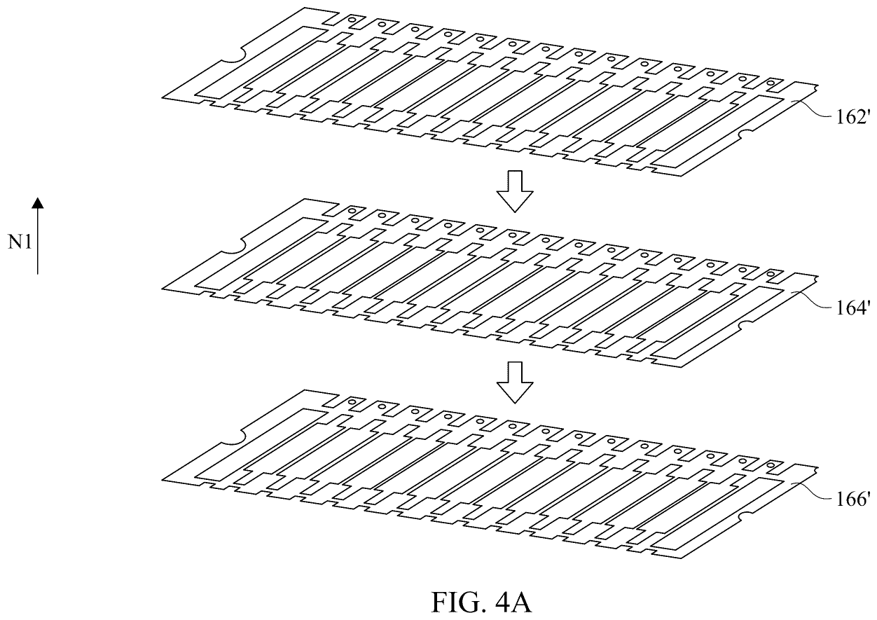

The conductive connecting component 160 is disposed on the surface 120s of the circuit substrate 120 and is located between the circuit substrate 120 and the circuit substrate 130. Referring to FIG. 2 and FIG. 3A, the conductive connecting component 160 includes a patterned metal layer 162, a patterned metal layer 164, a patterned metal layer 166 and an encapsulation layer 168. The patterned metal layer 162, the patterned metal layer 164, and the patterned metal layer 166 are stacked on each other in a direction N1, while the encapsulation layer 168 encapsulates the patterned metal layer 162, the patterned metal layer 164 and the patterned metal layer 166.

The materials of the patterned metal layer 162, the patterned metal layer 164 and the patterned metal layer 166 may be metals, such as copper, silver, aluminum, other similar metals or their alloys. The materials of the encapsulation layer 168 may include insulation materials, such as organic resins (e.g., epoxy resins) or other similar materials. It is worth mentioning, each of the patterned metal layers 162, the patterned metal layer 164 and the patterned metal layer 166 is substantially a lead frame in the embodiment, but the disclosure is not limited to the embodiment. Although there are three patterned metal layers as an example in the embodiment, the quantity of the patterned metal layer is not limited to the embodiment. In other embodiments, the quantity of the patterned metal layer may be one or more than one, such as two patterned metal layers or five patterned metal layers.

As shown in FIG. 2, the encapsulation layer 168 has a surface 168f and a surface 168s, while the surface 168f and the surface 168s extend long with the direction N1. Two end surfaces (i.e., two end surfaces 162e of the patterned metal layer 162) of each of the patterned metal layers are exposed on the surface 168f and the surface 168s of the encapsulation layer 168 separately, and two end surfaces (i.e., two end surfaces 162e of the patterned metal layer 162) of each of the patterned metal layers are flush with the surface 168f and the surface 168s separately.

Referring to FIG. 1, the end surfaces 162e (denoted in FIG. 2) of the patterned metal layer 162 in the conductive connecting component 160 are connected to the circuit substrate 120 and the circuit substrate 130 separately, while the circuit substrate 120 is electrically connected to the circuit substrate 130 through the patterned metal layer 162, the patterned metal layer 164 and the patterned metal layer 166 (shown in FIG. 3A) of the conductive connecting component 160. It is worth mentioning, the conductive adhesive materials S2 are disposed between the conductive connecting component 160 and the circuit substrate 120, and the conductive adhesive materials S3 are also disposed between the conductive connecting component 160 and the circuit substrate 130. Thus, the conductive connecting component 160 is electrically connected to the circuit substrate 120 through the conductive adhesive materials S2 and is electrically connected to the circuit substrate 130 through the conductive adhesive materials S3 in the embodiment.

Referring to FIG. 2 and FIG. 3A, each of the lead frames in the embodiment (i.e., each of the patterned metal layers) includes a plurality of leads. For example, the patterned metal layer 162 (i.e., one of the lead frames) includes a plurality of leads 162w; the patterned metal layer 164 includes a plurality of leads 164w, while the patterned metal layer 166 includes a plurality of leads 166w. The leads 162w, the leads 164w and the leads 166w are distributed in the encapsulation layer 168, and each of the leads is with a width and a thickness. Furthermore, a spacing is between the two leads adjacent to each other of the patterned metal layer 162, the patterned metal layer 164 and the patterned metal layer 166. To take the lead 162w in FIG. 3A as an example, the lead 162w has the width W1 and the thickness T1, while the spacing P1 is located between two leads 162w which are adjacent to each other.

It is worth mentioning, in some embodiments, the ratio of the width W1 and the thickness T1 of the lead 162w may be larger than 2, while the ratio of the width W1 and the spacing P1 of the lead 162w may be larger than 1. For example, in the embodiment of FIG. 3A, the width W1 of the lead 162w may be 0.8 mm, while the thickness T1 of the lead 162w may be 0.3 mm. Further, the spacing P1 between two adjacent leads 162w is smaller than 0.3 mm.

The encapsulation layer 168 further has a surface 168a and a surface 168b. The surface 168a and the surface 168b are adjacent to the surface 168f and the surface 168s, while the surface 168a overlaps the surface 168b in the direction N1. Each of the patterned metal layers which are adjacent to the surface 168a and the surface 168b has one plane, and the minimal distance between the planes and the surface 168a and the surface 168b is smaller than 0.2 mm. Specifically, the patterned metal layer 162 which is adjacent to the surface 168a has a plane 162s, and a minimal distance d1 between the plane 162s of the patterned metal layer 162 and the surface 168a is smaller than 0.2 mm, such as 0.1 mm. The patterned metal layer 166 which is adjacent to the surface 168b has a plane 166s, and a minimal distance d2 between the plane 166s of the patterned metal layer 166 and the surface 168b is 0.1 mm. In addition, the plane 162s overlaps the plane 166s in the direction N1.

In aforementioned embodiments, the widths (not denoted) of the lead 164w and the lead 166w are equal to the width W1 of the lead 162w (equal to 0.8 mm), but the thicknesses (not denoted) of the lead 164w and the lead 166w are 0.2 mm and 0.3 mm, respectively. The thickness T2 of the conductive connecting component 160 is the sum of the thicknesses of the lead 162w, the lead 164w and the lead 166w pluses the minimal distance d1 between the plane 162s and the surface 168a and the minimal distance d2 between the plane 166s and the surface 168b, so that the thickness T2 of the conductive connecting component 160 equals 1.0 mm.

The disclosure is not limited to the aforementioned embodiment, in another embodiment of FIG. 3B, the thickness T2 of the conductive connecting component 160 is 1.0 mm. However, the plane of one of the patterned metal layers is exposed on one of the surfaces of the encapsulation layer. Specifically, the plane 166s of the patterned metal layer 166 is exposed on the surface 168b of the encapsulation layer 168, while the minimal distance d1 between the plane 162s of the patterned metal layer 162 and the surface 168a is 0.1 mm. Furthermore, the thicknesses of the lead 162w, the lead 164w and the lead 166w are 0.3 mm. Since the sum of the thicknesses of the leads (i.e., the lead 162w, the lead 164w and the lead 166w) in this embodiment is larger than the sum of the thicknesses of the leads in the aforementioned embodiment, the conductive connecting component 160 in this embodiment is able to carry a larger current than the conductive connecting component 160 in the aforementioned embodiment.

Referring to FIG. 1, the semiconductor package module 100 further includes an adhesive layer 180. The adhesive layer 180 is disposed on the surface 168a (or the surface 168b) of the encapsulation layer 168 in the conductive connecting component 160 and is electrically connected to the conductive connecting component 160 and the second electronic component 150. The adhesive layer 180 may include such as adhesives, tapes or other similar materials.

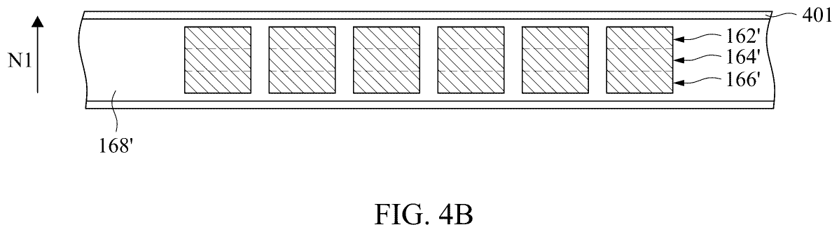

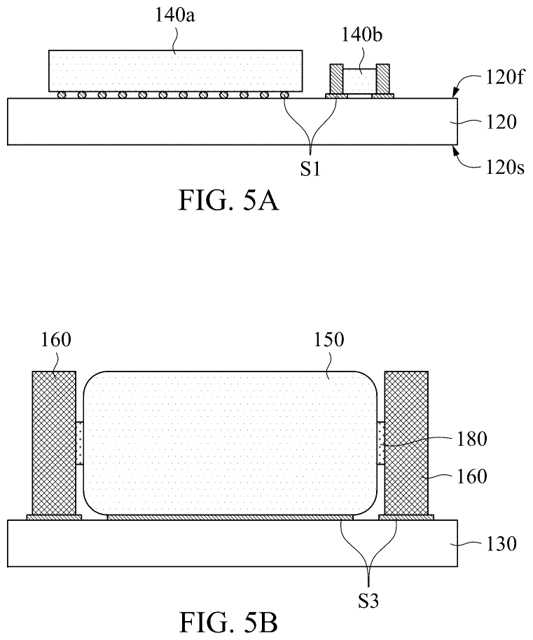

A method for fabrication of the conductive connecting component 160 is disclosed, while FIG. 4A to FIG. 4B illustrate sequent steps of this method in accordance with at least one embodiment of present disclosure. Referring to FIG. 4A, firstly, an initial patterned metal layer 162′, an initial patterned metal layer 164′ and an initial patterned metal layer 166′ are provided. It is worth mentioning, in the embodiment, the method of forming the initial patterned metal layer 162′, the initial patterned metal layer 164′ and the initial patterned metal layer 166′ may include but not limited to processing the initial lead frames (not shown) by stamping or etching so as to turn the initial lead frames into the initial patterned metal layer 162′, the initial patterned metal layer 164′ and the initial patterned metal layer 166′ shown in FIG. 4A.

Next, the initial patterned metal layer 162′, the initial patterned metal layer 164′ and the initial patterned metal layer 166′ are stacked along with the normal direction N1 of the initial patterned metal layer 162′, the initial patterned metal layer 164′ and the initial patterned metal layer 166′. In the embodiment, the initial patterned metal layer 162′, the initial patterned metal layer 164′ and the initial patterned metal layer 166′ completely overlap on one another in substance. In other words, the patterns (i.e., the lead patterns) of the initial patterned metal layer 162′, the initial patterned metal layer 164′ and the initial patterned metal layer 166′ are the same and are able to overlap on one another in the normal direction N1. Furthermore, in the process of stacking the initial patterned metal layer 162′, the initial patterned metal layer 164′ and the initial patterned metal layer 166′, the initial patterned metal layer 162′, the initial patterned metal layer 164′ and the initial patterned metal layer 166′ may be pressurized by a pressing a force ranging from 6 GPa to 12 GPa according to the requirements so as to compress the initial patterned metal layer 162′, the initial patterned metal layer 164′ and the initial patterned metal layer 166′ closely.

Referring to FIG. 4B, an initial encapsulation layer 168′ is formed on the initial patterned metal layer 162′, the initial patterned metal layer 164′ and the initial patterned metal layer 166′ by pre-molding after the initial patterned metal layer 162′, the initial patterned metal layer 164′ and the initial patterned metal layer 166′ are stacked. The pre-molding may include forming methods of encapsulation materials, such as the transforming molding or other similar molding methods. For example, the initial patterned metal layer 162′, the initial patterned metal layer 164′ and the initial patterned metal layer 166′ which are stacked may be disposed inside a mold 401, and the mold 401 are filled with the fluid molding compound.

The initial encapsulation layer 168′ encapsulates the initial patterned metal layer 162′, the initial patterned metal layer 164′ and the initial patterned metal layer 166′. The initial encapsulation layer 168′ of the embodiment may encapsulate the initial patterned metal layer 162′, the initial patterned metal layer 164′ and the initial patterned metal layer 166′ completely, but the disclosure is not limited to the embodiment. That is, the initial encapsulation layer 168′ may expose a part of the initial patterned metal layer 162′, the initial patterned metal layer 164′ and the initial patterned metal layer 166′ in other embodiments.

The initial encapsulation layer 168′, the initial patterned metal layer 162′, the initial patterned metal layer 164′ and the initial patterned metal layer 166′ are cut by the mechanical cutting, the laser cutting or the focused ion bean machining after the initial encapsulation layer 168′ is formed so as to form the encapsulation layer 168, the patterned metal layer 162, the patterned metal layer 164 and the patterned metal layer 166 shown in FIG. 3A. Thus, the conductive connecting component 160 in FIG. 2 and FIG. 3A is approximately completed.

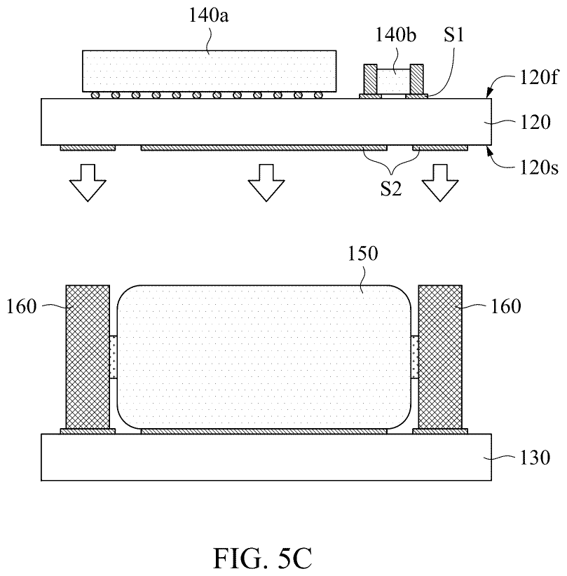

A method for fabrication of the semiconductor package module 100 is disclosed, while FIG. 5A to FIG. 5C illustrate sequent steps of this method in accordance with at least one embodiment of present disclosure. Referring to FIG. 5A, firstly, the circuit substrate 120 is provided, and the conductive adhesive materials S1 are disposed on the surface 120f of the circuit substrate 120 by printing. Next, the first electronic component 140a and the first electronic component 140b are disposed on the conductive adhesive materials S1 by methods, such as reflowing or curing. In addition, referring to FIG. 5B, the circuit substrate 130 is provided, and the conductive adhesive materials S3 may be disposed on the surface (not denoted) of the circuit substrate 130 by printing. Next, the second electronic component 150 and the conductive connecting component 160 are disposed on the conductive adhesive materials S3 by reflowing or curing.

It is worth mentioning, in some embodiments, the adhesive layer 180 may be disposed on the second electronic component 150, and then the conductive connecting component 160 may be disposed on the adhesive layer 180 so as to make the conductive connecting component 160 electrically connected to the second electronic component 150. Next, the second electronic component 150 and the conductive connecting component 160 are disposed on the conductive adhesive materials S3 which are already disposed on the circuit substrate 130.

Referring to FIG. 5C, after the first electronic component 140a and the first electronic component 140b are disposed on the circuit substrate 120, and after the second electronic component 150 is disposed on the circuit substrate 130, the conductive adhesive materials S2 are disposed on the surface 120s of the circuit substrate 120. Next, the surface 120s of the circuit substrate 120 are turned toward the circuit substrate 130 on the second electronic component 150, and the circuit substrate 120 is disposed on the second electronic component 150. The second electronic component 150 is connected to the conductive adhesive materials S2 by methods, such as reflowing or curing. Thus, the semiconductor package module 100 in FIG. 1 is approximately completed.

In conclusion, the conductive connecting component of at least one embodiment of the disclosure is formed by stacking a plurality of patterned metal layers and then forming an encapsulation layer encapsulating the plurality of patterned metal layers, so that the plurality of patterned metal layers are fastened. In the fabrication process, the thickness of the encapsulation layer may be reduced since the stacked patterned metal layers are hardly to be moved. Specifically, the patterned metal layers may be fastened by encapsulating the encapsulation layer whose thickness is smaller than 0.2 mm. Therefore, the thicknesses of the patterned metal layers may be increased so as to increase the current carrying capacity of the conductive connecting component without thickening the conductive connecting component.

In addition, since the end surfaces of the patterned metal layers are flush with the first surface of the encapsulation layer, the interface (i.e., the surface 168f and the surface 168s of the encapsulation layer 168) between the conductive connecting component and the circuit substrate is flat. As a result, additional flattening processes may be omitted in the fabricating process of the semiconductor package module so as to simplify the fabricating process and reduce the cost.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A conductive connecting component, comprising:
a plurality of patterned metal layers stacked on each other in one direction; and
an encapsulation layer encapsulating the plurality of patterned metal layers, and the encapsulation layer has two first surfaces opposite to each other, and the first surfaces extend along with the direction, wherein two end surfaces of each of the patterned metal layers are exposed on the first surfaces of the encapsulation layer separately, and the end surfaces of each of the patterned metal layers are flush with the first surfaces of the encapsulation layer separately.

2. The conductive connecting component of claim 1, wherein each of the patterned metal layers is a lead frame.

3. The conductive connecting component of claim 2, wherein each of the patterned metal layers comprises:
a plurality of leads distributed in the encapsulation layer, wherein each of the leads is with a width and a thickness, and a ratio of the width and the thickness is larger than 2.

4. The conductive connecting component of claim 3, wherein a spacing is between two of the leads adjacent to each other of each of the patterned metal layers, and the ratio of the width and the thickness of the leads is larger than 1.0.

5. The conductive connecting component of claim 4, wherein the spacing between two of the leads adjacent to each other is smaller than 0.3 mm.

6. The conductive connecting component of claim 1, wherein the encapsulation layer further has two second surfaces opposite to each other, and the second surfaces are adjacent to the first surfaces, wherein each of the patterned metal layers adjacent to the second surfaces has one plane, and a minimal distance between the plane and the second surfaces is smaller than 0.2 mm.

7. The conductive connecting component of claim 6, wherein the plane of one of the patterned metal layers is exposed on one of the second surfaces of the encapsulation layer.

8. A semiconductor package module, comprising:
a first circuit substrate;
a second circuit substrate disposed on the first circuit substrate oppositely, and the second circuit substrate has a third surface and a fourth surface opposite to each other;
a first electronic component disposed on the third surface of the second circuit substrate and electrically connected to the second circuit substrate;
a second electronic component disposed on the fourth surface of the second circuit substrate, wherein the second electronic component is located between the first circuit substrate and the second circuit substrate and electrically connected to the first circuit substrate and the second circuit substrate; and
a conductive connecting component of claim 1 disposed on the fourth surface of the second circuit substrate and located between the first circuit substrate and the second circuit substrate, wherein the end surfaces of each of the patterned metal layers of the conductive connecting component are connected to the first circuit substrate and the second circuit substrate separately, and the first circuit substrate is electrically connected to the second circuit substrate through the patterned metal layers of the conductive connecting component.

9. The semiconductor package module of claim 8, further comprising:
an adhesive layer disposed on one of the second surfaces of the encapsulation layer of the conductive connecting component and connected to the conductive connecting component and the second electronic component.

10. A method for fabrication of a conductive connecting component, comprising:
providing a plurality of initial patterned metal layers;
stacking the plurality of initial patterned metal layers along with a normal direction of the plurality of initial patterned metal layers;
forming an initial encapsulation layer on the plurality of initial patterned metal layers after the plurality of initial patterned metal layers are stacked on each other, wherein the initial encapsulation layer encapsulates the plurality of initial patterned metal layers; and
cutting the initial encapsulation layer and the plurality of initial patterned metal layers after the initial encapsulation layer is formed to form an encapsulation layer and a plurality of patterned metal layers, and the encapsulation layer has two first surfaces opposite to each other, and the first surfaces extend along with the normal direction, wherein two end surfaces of each of the patterned metal layers are exposed on the first surfaces of the encapsulation layer separately, and the end surfaces of each of the patterned metal layers are flush with the first surfaces of the encapsulation layer separately.
